(19) United States
(12) Patent Application Publication
(10) Pub. No.: US 2009/0323286 A1
(43) Pub. Date: Dec. 31, 2009

(54) APPARATUS FOR REMOVING HEAT FROM PC CIRCUIT BOARD DEVICES SUCH AS GRAPHICS CARDS AND THE LIKE

(75) Inventor: Tai-Sheng (Andrew) HAN, Fullerton, CA (US)

Correspondence Address: IPxLAW Group LLP, 95 South Market Street, Suite 570, San Jose, CA, 95113, US

(73) Assignee: EVGA CORPORATION, Brea, CA (US)

(21) Appl. No.: 12/485,031

(22) Filed: Jun. 15, 2009

Related U.S. Application Data
(60) Provisional application No. 61/132,004, filed on Jun. 13, 2008.

(51) Int. Cl. H05K 7/20

(52) U.S. Cl. 361/702

(57) ABSTRACT

Apparatus for removing thermal energy from PC circuit board devices such as graphics cards and the like, and including a waterblock adapted to be positioned on one side of a graphics cards, or the like, a heat sink adapted to be secured to the opposite side of the card, and a bridge plate adapted to extend over an edge of the card and be sandwiched between the heat sink and waterblock to serve as a means for coupling heat from the heat sink to the waterblock where it can be transferred to a liquid coolant and transported to an external radiator for disposal. The heat sink may include radiating vanes and an associated heat pipe for enhancing transport of thermal energy collected by the heat sink to the bridge plate.

### FIELD OF THE INVENTION

The present invention relates to a new device for removing heat from PC circuit board apparatus such as graphics cards, and the like, which generate substantial heat when in operation, and, more particularly, to liquid cooled waterblocks for transferring thermal energy from electronic components to a liquid flowstream.

### BACKGROUND OF THE INVENTION

Microprocessors are at the heart of most computing systems, and whether the system is a desktop computer, a laptop computer, a communication system, a television, etc., processors are often the fundamental building block of the system and may be deployed as central processing units (CPU), graphics processing units (GPU), memories, controllers, etc.

With the advance of computer operating speeds, the thermal energy generated by active components of the computer, such as the processor and memory devices, often becomes significant. Furthermore, in order to enable desktop and other computers to rapidly process graphics and game technology, add-on units generally referred to as “graphics cards” or “VGA” cards” are often installed in computer devices. Such cards include a separate processor, called a GPU, one or more high speed memory devices, and other required circuitry, all mounted to a second circuit board including an edge connector that is adapted to plug into an available slot in the associated computer device. Typically, GPU and/or memory chips generate substantial heat that if not dissipated will adversely affect operation of not only the graphics card, but perhaps the entire computer.

With the advancement of computing systems, the power of the processors driving these systems has dramatically increased. The speed and power of the processors has bee achieved by using new combinations of materials and by populating the processor with a larger number of processing circuits. As a consequence, the increased circuitry per unit area of the processor as well as the conductive properties of the materials used to build the processors has resulted in the generation of more and more heat. Further, as these computing systems have become more sophisticated, additional processors have been implemented within the computing system and thus contribute additional heat. In addition to the processors, other systems operating within the computing system may also generate significant heat and add to the heat experienced by the processors.

Many adverse effects may result from the increased heat. At one end of the spectrum, the processor may begin to malfunction and incorrectly process information. For example, when the circuits of a processor are implemented with digital logic devices, the logic devices may incorrectly register a logical zero or a logical one, or logical zeros may be mistaken as logical ones and vice versa. Moreover, when a processor becomes overheated, it may experience a physical breakdown in its structure. For example, the metallic leads or wires connected to the core of the processor may begin to melt, and/or the structure of the semiconductor material itself may breakdown once certain heat thresholds are met. These types of physical breakdowns may be irreversible and render the processor and the computing system inoperable and un-repairable.

A number of approaches have been implemented to address the issue of processor heating. Initial approaches focused on either cooling the air outside of the computing system, cooling the air inside the computing system, or a combination of both. An early approach was to cool the ambient environment using various types of air conditioning systems. But such solution was costly to build and operate, thus making the cold room impractical for this type of user.

Another conventional cooling technique focused on cooling the air surrounding the processor within the computing system. This approach was implemented initially by providing simple ventilation holes or slots in the chassis of the computing system, and subsequently, by deploying a fan in the housing of the computing system. However, as processors became more densely populated with circuitry and as the number of processors implemented in a computing system increased, simply exchanging the air within the housing could no longer dissipate the necessary amount of heat from the processor or the chassis of the computing system.

Other conventional methods of cooling computing systems have included the addition of sophisticated heat sink designs that can, in combination with various types of air blowers, remove the vast amounts of heat that can be generated by a modern processor. However, the size of the heat sink is directly proportional to the amount of heat that can be dissipated by the sink, and thus the more heat to be dissipated, the larger the heat sink required. Although larger heat sinks can be utilized, the size of the heat sink can become so large that this solution becomes infeasible.

Refrigeration techniques and heat pipes have also been used to dissipate heat from a processor. However, these techniques have limitations. Refrigeration requires substantial additional power which drains the battery in a portable computing system. In addition, condensation and moisture, which is damaging to the electronics in computing systems, typically develops when using the refrigeration techniques. Heat pipes provide yet another alternative; however, conventional heat pipes have proven to be ineffective in dissipating the large amount of heat generated by a processor.

Consequently, the heat produced by processors is quickly exceeding the levels that can be cooled using even specialized combinations of the air-cooling techniques mentioned above.

More recently, heat removal systems have been implemented wherein a liquid is used to remove heat from heat exchangers disposed within the chassis, and in intimate relationship with the sources of heat, so that it can be dissipated outside of the computer housing. However, because space is limited within the computer housings it is necessary that the heat exchanger be small and highly efficient. Further, as a result of the competitive nature of the electronics industry, the additional cost for any new type of heat dissipation apparatus must be very low or incremental.

Although a number of designs have been proposed and used to couple thermal energy from processors, such designs have in large part been similar in design to previous embodiments using air as the heat transporting fluid. When such designs are used to transport the more viscous liquid coolants, they do not usually achieve efficient heat transfer and often generate flow resistances that require substantial pumping power to move the fluid through the system.

There is thus a need in the art for improved fluid handling apparatus for use in cooling computing systems and the processors deployed within the system. There is also a need in the art for optimal, cost-effective apparatus for cooling processors so that they may operate at marketed operating capacities. Moreover, there is a need for improved fluidic heat transfer and removal apparatus that can be deployed within the small footprint available in laptop computers, desktop, and other processing systems.

### SUMMARY OF THE INVENTION

Briefly, a presently preferred embodiment of the present invention includes a waterblock adapted to be positioned on one side of a graphics cards, or the like, a heat sink adapted to be secured to the opposite side of the card, and a bridge plate adapted to extend over an edge of the card and be sandwiched between the heat sink and waterblock to serve as a means for coupling heat from the heat sink to the waterblock where it can be transferred to a liquid coolant and transported to an external radiator for disposal. The heat sink may include radiating vanes and an associated heat pipe for enhancing transport of thermal energy collected by the heat sink to the bridge plate.

A principal objective of the illustrated embodiment is provide a means for exchanging the maximum amount of heat per unit area by generating as much turbulence in the flow stream as possible without contributing material flow resistance. This embodiment utilizes the design of the flow channel and the offset positioning and design of the vanes or fins which extend the surface area of the heat transferring metal into the flow channel to accomplish this purpose.

### IN THE DRAWINGS

FIG. 1 is a schematic perspective view generally showing one side of a thermal energy transfer device, in accordance with the present invention;

FIG. 2 is a schematic perspective view generally showing the other side of the thermal energy transfer device depicted in FIG. 1;

FIG. 3 is an elevational view of the thermal energy transfer device as viewed in the direction indicated by the arrows 3-3 of FIG. 2;

FIG. 4 illustrates the outside surface of the main heat transfer plate adapted to engage the electronic components to be cooled;

FIG. 5 illustrates the interior side and flow channel details of the main heat transfer plate;

FIG. 5a is a partial schematic perspective view generally showing one of the E-shaped vanes formed on the interior surface of the main heat transfer plate;

FIG. 6 illustrates the finned exterior side of the secondary heat transfer plate; and

FIG. 7 illustrates the interior side of the secondary heat transfer plate.

### DETAILED DESCRIPTION

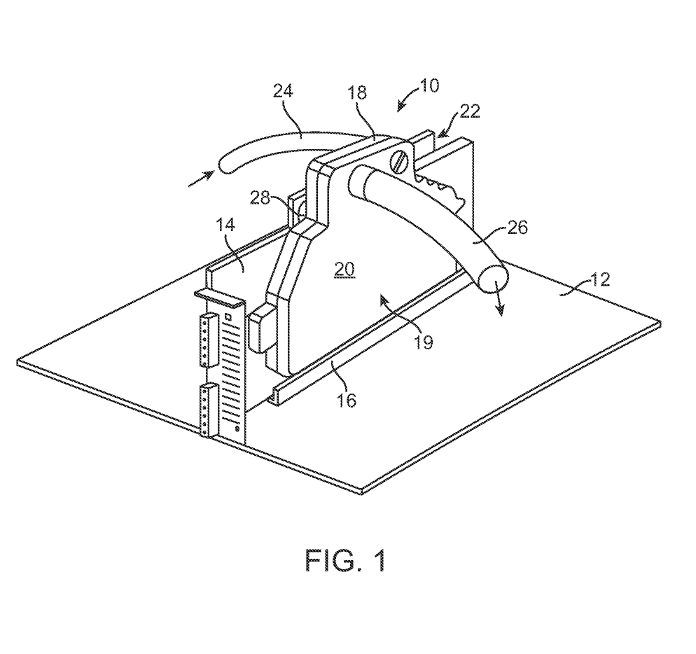

Referring now to FIG. 1 of the drawings, one embodiment of a thermal energy transfer device in accordance with the present invention is depicted at 10 and shown operatively affixed to a graphics card 14 mounted in an expansion slot 16 of a PC “motherboard board” 12 of a computer system.

In the illustrated embodiment, the device 10 is in the form of an assembly that includes, on one side of the card 14, a waterblock 19 that includes a main heat transfer plate 18, typically made of copper or other good thermally conductive material, and a cover plate 20 which, in the illustrated embodiment, is made of DELRIN, and on the other side of the card 14, a finned secondary heat transfer plate or heat sink 22 made of a good heat conductive material such as aluminum. An upper portion of the heat sink 22 is thermally connected to the plate 18 by means of a bridging connection 28 not clearly shown in this figure.

The upper portion of the assembly includes a pair of cooling fluid inlet and outlet ports to which flexible conduits 24 and 26 are joined to circulate fluid coolant through the waterblock 19. The other ends of the conduits are connected to a pump and radiator or other heat exchanger means (not shown) typically mounted outside the chassis or housing of the computer system. Although the term “waterblock” is used herein, it will be appreciated that other coolant fluids besides water may be used in this embodiment.

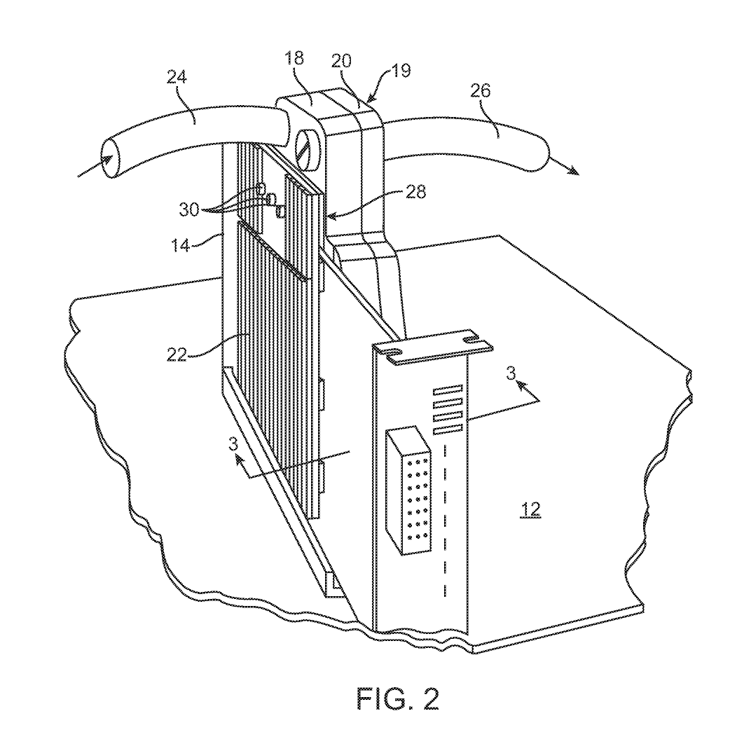

Referring now to FIG. 2, the opposite side of the assembly is shown to reveal details of the finned exterior of the secondary heat transfer mechanism or heat sink 22. This view also shows the positioning of the bridging connector between the heat sink 22 and the plate 18. Note that the connector extends across the top edge of card 14. As will be more clearly shown and described below, the assembly including the heat sink 22, bridging connector 28 and waterblock 19 is held together and clamped across the card 14 by three screws or bolts 30. Other fasteners (not shown) may also be used to fasten the assembly to the card.

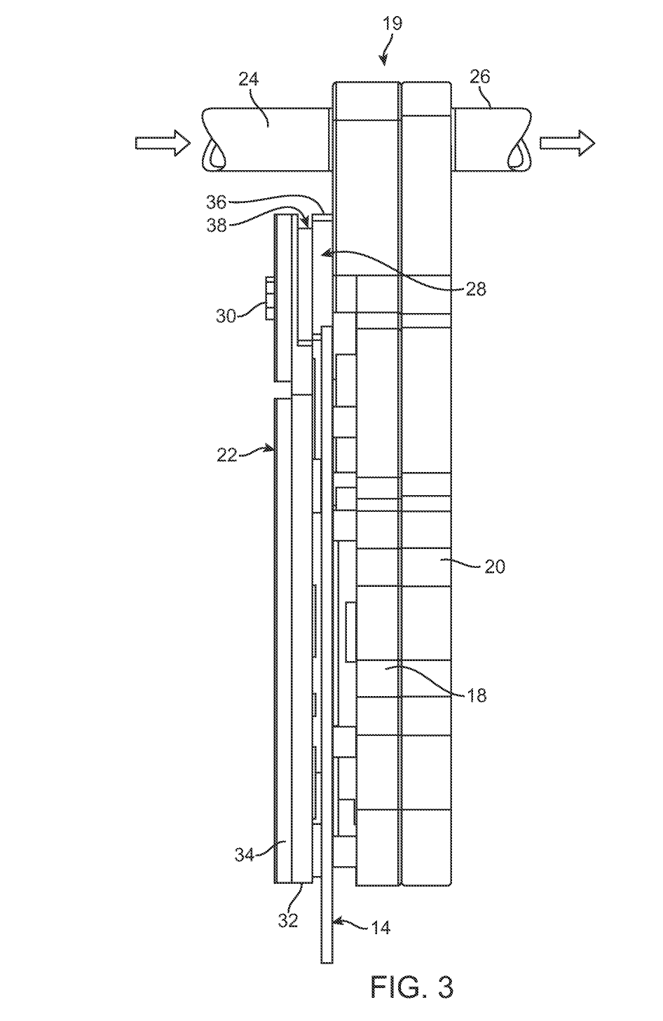

FIG. 3 is an elevational view pictorially showing the relationship between the waterblock 19, heat sink 22 and bridging connector 28. Details of these elements will follow below, but briefly, note that the heat sink 22 includes a metal plate 32, perhaps made of copper or aluminum, that on one side may be adapted to engage the card surface and/or specific sources of heat or board surface areas on one side of the card 14. Extending across separated upper portions of the plate 32, and across the entire mid and lower portions of the plate are a plurality of black anodized heat radiating fins 34. Note also that the bridging connection 28 includes a conductive metal plate 36 and a heat pipe 38, both of which are sandwiched between heat sink 22 and plate 18. As indicated above, the assembly is held together by the screws or bolts 30.

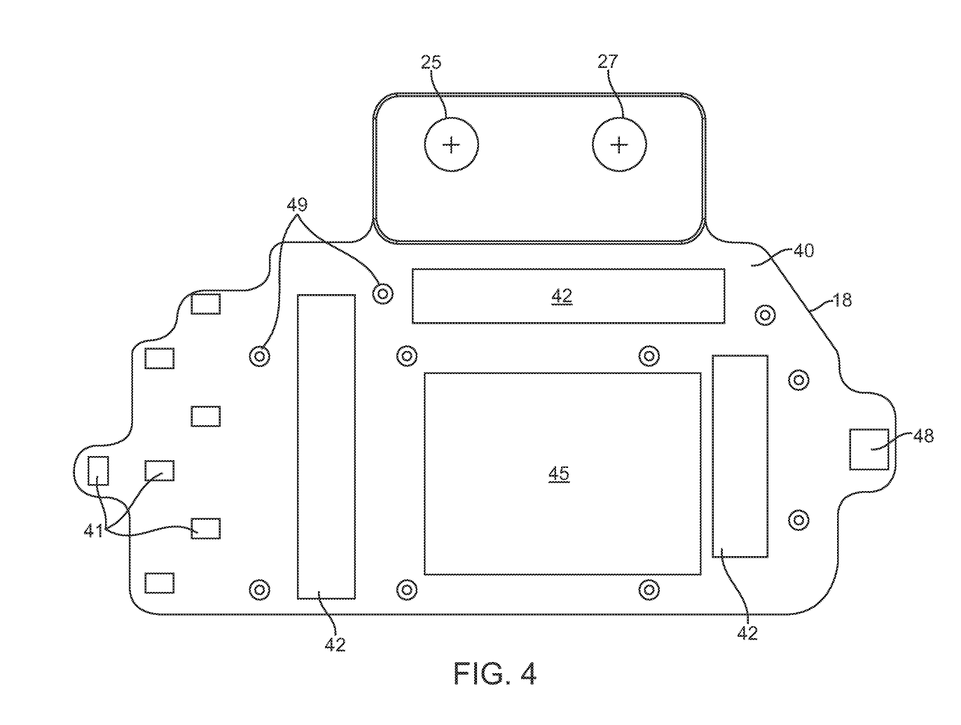

FIG. 4 illustrates various details of the exterior side or face 40 of the plate 18 including an inlet port 25 to which the tube 24 is secured, and an outlet port 27 to which the tube 26 is secured as shown in FIGS. 1 and 2. Also provided on the face 40 are a plurality of raised surface areas 41, 43 and 45 for intimately engaging various electronic components on card 14. The larger region 45 is specifically intended to engage the outer surface of the GPU. A conductive glue or grease may be used to enhance the heat transfer between the respective surfaces. Also shown are a plurality of bolt holes adapted to receive the plurality of bolts used to secure the plate 18 to the outer plate 20.

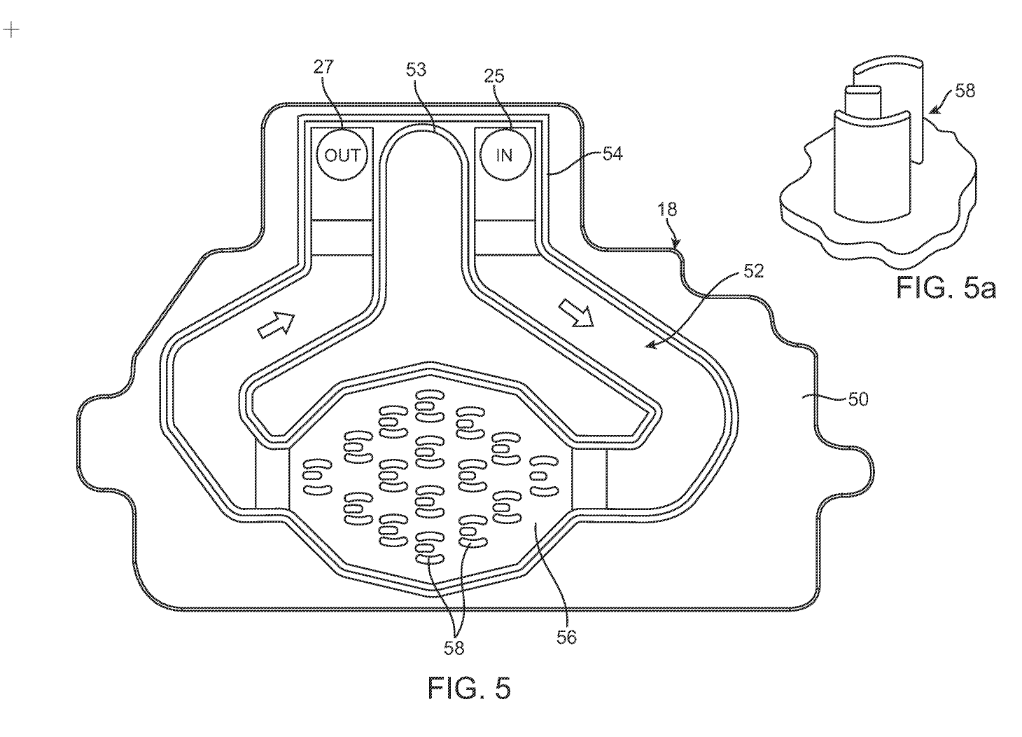

FIG. 5 illustrates the interior side or face of plate 18 and shows the fluid flow channel 40 formed of broadly grooved or recessed regions of the surface of the plate on the side which will face and be covered by and attached to the cover plate 20. The channel 40 is molded or machined into the plate 18 and is circumscribed by narrow grooves 42 and 44 that are adapted to receive resilient “O-rings” which when engaged by the cover plate 20 form seals about the inner and outer boundaries of the channel 40. Note that the channel 40 is of a generally diamonded shape to maximize surface contact with the fluid passing therethrough from the inlet aperture 25 to the outlet aperture 27. Note also that the lower part of the channel 40 is widened at 46, the portion opposite the region 45 on the other side which will overlie and engage the GPU on the graphics card 14.

The channel portion 46 is provided with a plurality of upstanding three-part generally E-shaped vane assemblies 48, perhaps more clearly illustrated in FIG. 5a, that preferably extend through the channel to engage the facing surface of the cover plate 20 when it is attached. It will thus be appreciated that with the DELRIN plate 20 (FIG. 1) secured in place over the plate 18 a continuous flow channel will be created that extends from the inlet port 25 to the outlet port 27. The vanes 48 serve to disrupt the flow of fluid in the region 46 as it passes therethrough so as to create heat exchange enhancing turbulence in the flow across the GPU without materially increasing the flow resistance in the channel.

Although turbulent flow may require a slightly higher input of energy from the flow causing pump than would be the case if the flow was laminar it is generally recognized that turbulent flow is essential for good heat transfer.

The (dimensionless) Reynolds number characterizes whether flow conditions lead to laminar or turbulent flow; e.g. for a flow path of this type, it is believed that a Reynolds number above about 4000 (a Reynolds number between 2100 and 4000 is known as transitional flow) will be turbulent. At very low speeds the flow is laminar, i.e., the flow is smooth (though it may involve small vortices). However, as the flow speed is increased, at some point a transition is made to turbulent flow wherein unsteady vortices appear will interact with each other.

In this embodiment, with a fluid flowing through the channel the rate of heat transfer between the bulk of the fluid in the channel and the external surface of plate 18 beneath the channel can be roughly calculated as:

$$Q = ( \frac{1}{\frac{1}{h} + \frac{t}{k }} ) \cdot A \cdot Δ T$$

where
Q=heat transfer rate (W)
h=heat transfer coefficient (W/(m²·K))
t=plate thickness (m)
k=plate thermal conductivity (W/m·K)

The heat transfer coefficient is the heat transferred per unit area per Kelvin. Thus, area is included in the equation as it represents the area over which the transfer of heat takes place. The thermal resistance due to the channel wall and the vane surfaces may be roughly calculated by the following relationship:

$$R = \frac{x}{k \cdot A}$$

where
x=the plate thickness (m)
k=the thermal conductivity of the material (W/mk)
A=the total area of the channel (m²)

This represents the heat transfer by conduction in the channel.

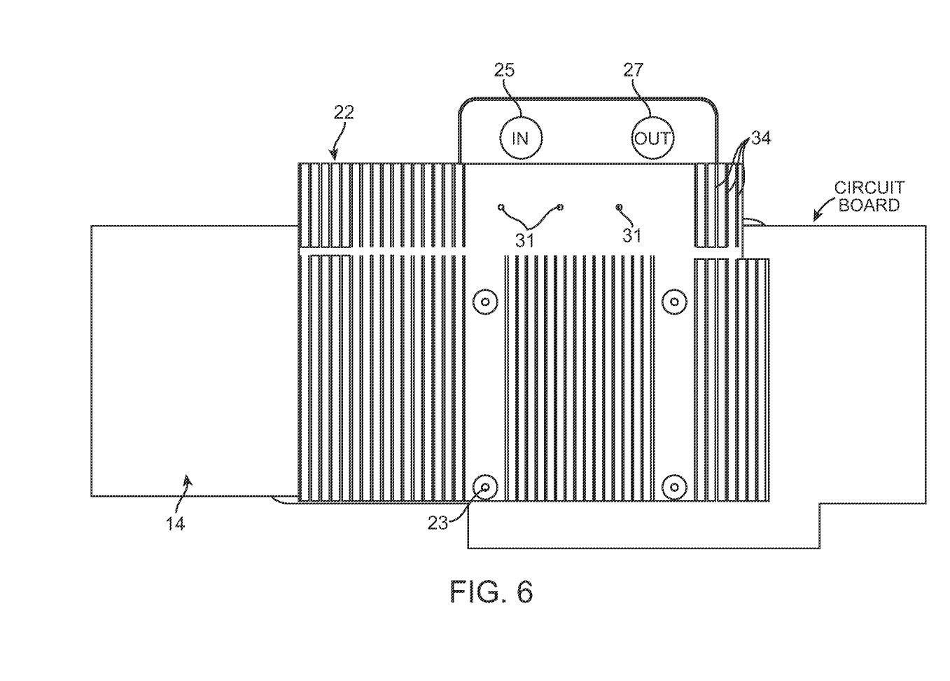

FIG. 6 shows the outer side of the heat sink 22 with its heat radiating ribs 34, mounting screw receiving holes 23 and bridge fastening holes 31 for receiving the bolts or screws 30 shown in FIG. 3.

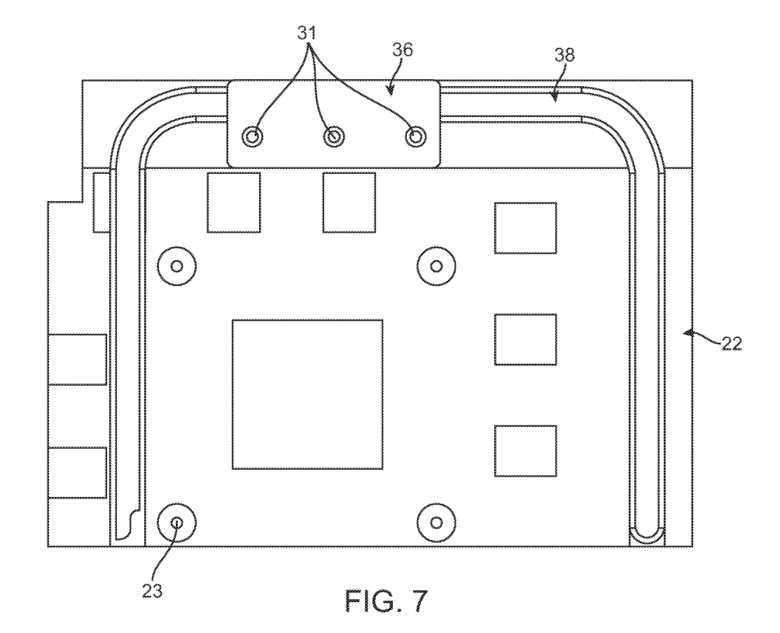

FIG. 7 illustrates at a slightly larger scale the inner side of heat sink 22, and shows the inverted U-shaped heat pipe 38 and conductive metal bridge plate 36, as well as bolt holes 23 for securing the heat sink to the card 14. With the heat sink 22 secured to the waterblock 19, heat collected by the plate 32 and not radiated into the environment via the vanes 34 will be communicated by the heat pipe 38 to the bridge plate 36 and coupled into the plate 18 where it will be transferred to the fluid in the flow channel and transported through the outlet port 27 and tube 26 to an external radiator for removal.

Although details of the present invention have been shown and described above in terms of a single embodiment, it will be appreciated that other embodiments can be implemented as well without departing from the true spirit and scope of the invention. For example, in an alternative embodiment, a second finned heat sink plate might be substituted for the DELRIN cover plate 20. In still another embodiment, another waterblock might be substituted for the heat sink 22 or sandwiched between the heat sink 22 and the card 14. In yet another embodiment, a single waterblock might be configured to have a medial slot formed therein to receive and thereby surround the card 14.

1. Apparatus for removing thermal energy from a circuit board device, comprising:
waterblock means adapted to be positioned on one side of the board device for collecting thermal energy from at least one heat generating component on the board device and transferring the thermal energy to a fluid coolant flowing through the waterblock means;
heat sink means adapted to be positioned on the opposite side of the board device for collecting thermal energy from the opposite side of the board device; and
bridge means adapted to extend over an edge of the board device and be sandwiched between the heat sink means and the waterblock means, said bridge means being operative to couple thermal energy from the heat sink means to the waterblock means where it can be transferred to the fluid coolant and transported to an external radiator for disposal.

2. Apparatus for removing thermal energy from a circuit board device as recited in claim 1 wherein said waterblock means includes a flow channel formed therein and has vanes extending into the flow channel to create turbulence in the fluid coolant flowing therethrough.

3. Apparatus for removing thermal energy from a circuit board device as recited in claim 2 wherein the flow channel is configured in a diamond shape overlying a region of the waterblock intended to receive transfer of thermal energy from the heat generating component to the fluid coolant.

4. Apparatus for removing thermal energy from a circuit board device as recited in claim 1 wherein said heat sink means includes a plurality of outwardly extending ribs for radiating thermal energy collected from the opposite side of the board device into the ambient environment.

5. Apparatus for removing thermal energy from a circuit board device as recited in claim 4 wherein said waterblock means includes a flow channel formed therein and has vanes extending into the flow channel to create turbulence in the fluid coolant flowing therethrough, and wherein said heat sink means further includes a heat pipe for collecting thermal energy around at least a portion of the perimeter of said heat sink means and transferring it to said bridge means.

6. Apparatus for removing thermal energy from a circuit board device as recited in claim 1 wherein said waterblock means includes a metallic plate having an inlet port, an exit port and at least one flow channel formed therein, said flow channel being operative to direct the fluid coolant from said inlet port to said exit port.

7. Apparatus for removing thermal energy from a circuit board device as recited in claim 6 wherein said flow channel is in the form of an open groove formed in said metallic plate, and wherein said waterblock means further includes a cover plate affixed to said metallic plate and serving to form a closure over the open groove thereby forming a closed conduit forming the flow channel.

8. Apparatus for removing thermal energy from a circuit board device as recited in claim 2 wherein said waterblock means includes a metallic plate having an inlet port, an exit port and said flow channel formed therein, said flow channel leading from said inlet port to said exit port, and wherein said vanes are in the form of upstanding, multiple part vane subassemblies that extend outwardly from said metallic plate and into the flow channel.

9. Apparatus for removing thermal energy from a circuit board device as recited in claim 8 wherein the flow channel is configured in a generally diamond shape overlying a region of the waterblock intended to receive transfer of thermal energy from at least one heat generating component on the circuit board.

10. Apparatus for removing thermal energy from a circuit board device as recited in claim 1 wherein said waterblock means includes a metallic plate having an inlet port, an exit port and a flow channel formed therein, said flow channel leading from said inlet port to said exit port, and vanes in the form of upstanding, multiple-part vane subassemblies extending outwardly from said metallic plate and into the flow channel to create turbulence in the fluid coolant flowing therethrough.

11. Apparatus for removing thermal energy from a circuit board device as recited in claim 2 wherein the transverse width of said flow channel is enlarged in a region of said waterblock means intended to overlie a portion of the board device carrying a thermal energy generating component, and wherein said vanes are disposed in said enlarged region and are in the form of upstanding, multiple-part vane subassemblies that extend outwardly from said metallic plate and through the flow channel to engage a facing surface of a cover plate affixed to said metallic plate.

12. Apparatus for removing thermal energy from a circuit board device as recited in claim 6 wherein the transverse width of said flow channel is enlarged in a region of said waterblock means intended to overlie a portion of the board device carrying a thermal energy generating component

13. Apparatus for removing thermal energy from a circuit board device as recited in claim 12 wherein said heat sink means includes a plurality of outwardly extending ribs for radiating thermal energy collected from the opposite side of the board device into the ambient environment.

14. Apparatus for removing thermal energy from a circuit board device as recited in claim 8 wherein said vane subassemblies include a first element having a first concave surface facing in a direction transverse to the flowstream in said flow channel, and a second element having a second concave surface facing said first concave surface.

15. Apparatus for removing thermal energy from a circuit board device as recited in claim 14 wherein said vane subassemblies further include a third element disposed between said first and second elements.

16. Apparatus for removing thermal energy from a circuit board device as recited in claim 7 wherein a narrow groove is formed on each side of said flow channel for receiving an O-ring sealing member adapted to sealingly engage said cover plate.

17. Apparatus for removing thermal energy from a circuit board device as recited in claim 16 wherein said heat sink means further includes a heat pipe for collecting thermal energy around at least a portion of the perimeter of said heat sink means and transferring it to said bridge means.

18. Apparatus for removing thermal energy from a circuit board device as recited in claim 2 wherein the transverse width of said flow channel is enlarged in a region of said waterblock means intended to overlie a portion of the board device carrying a thermal energy generating component.

19. Apparatus for removing thermal energy from a circuit board device as recited in claim 5 wherein the transverse width of a portion of said flow channel is enlarged in a region of said waterblock means intended to overlie a portion of the board device carrying a thermal energy generating component.

20. Apparatus for removing thermal energy from a circuit board device as recited in claim 10 wherein the transverse width of said flow channel is enlarged in a region of said waterblock means intended to overlie a portion of the board device carrying a thermal energy generating component.

21. Apparatus for removing thermal energy from a circuit board device as recited in claim 12 and further comprising vane subassemblies disposed in said enlarged region and including a first element having a first concave surface facing in a direction transverse to the flowstream, and a second element having a second concave surface facing said first concave surface to create turbulence in the fluid coolant flowing therethrough.

22. Apparatus for removing thermal energy from a circuit board device as recited in claim 21 wherein said vane subassemblies further include a third element disposed between said first and second elements.

23. Apparatus for removing thermal energy from a circuit board device as recited in claim 22 wherein the enlarged portion of said flow channel is generally configured in a four point diamond shape having a first point communicatively coupled to said inlet port, and a second point communicatively coupled to said exit port.

24. Apparatus for removing thermal energy from a circuit board device as recited in claim 20 wherein the enlarged portion of said flow channel is generally configured in a four point diamond shape having a first point communicatively coupled to said inlet port, and a second point communicatively coupled to said exit port.
